(19) United States
(12) Patent Application Publication
(10) Pub. No.: US 2025/0031392 A1
(43) Pub. Date: Jan. 23, 2025

(54) SHUNT RESISTANCE, METHOD OF MANUFACTURING SHUNT RESISTANCE, AND SEMICONDUCTOR DEVICE

(71) Applicant: ROHM Co., LTD., Kyoto (JP)

(72) Inventor: Kosaku Tanaka, Kyoto (JP)

(21) Appl. No.: 18/775,613

(22) Filed: Jul. 17, 2024

(30) Foreign Application Priority Data
Jul. 18, 2023 (JP) 2023-116451

(51) Int. Cl. H01C 1/14; H01C 17/28; H01L 23/31; H01L 23/373; H01L 25/07; H01L 25/16

(52) U.S. Cl. CPC H01L 28/20; H01C 1/14; H01C 17/28; H01L 23/3142; H01L 23/3733; H01L 25/072; H01L 25/16

(57) ABSTRACT

Provided is a shunt resistance including a resistive element layer, a first electrode layer laminated on a first side in a thickness direction of the resistive element layer, and a second electrode layer laminated on a second side in the thickness direction of the resistive element layer.

### CROSS REFERENCE TO RELATED APPLICATIONS

This application claims priority benefit of Japanese Patent Application No. JP 2023-116451 filed in the Japan Patent Office on Jul. 18, 2023. Each of the above-referenced applications is hereby incorporated herein by reference in its entirety.

### BACKGROUND

The present disclosure relates to a shunt resistance, a method of manufacturing the shunt resistance, and a semiconductor device.

Japanese Patent Laid-Open No. 2022-163238 discloses an example of a resistor in related art. The resistor disclosed in Japanese Patent Laid-Open No. 2022-163238 includes a resistive element and a pair of electrodes. This resistor is configured as a shunt resistor.

### BRIEF DESCRIPTION OF THE DRAWINGS

FIG. 1 is a perspective view illustrating a shunt resistance according to a first embodiment of the present disclosure;

FIG. 2 is a sectional view illustrating the shunt resistance according to the first embodiment of the present disclosure;

FIG. 3 is a sectional view illustrating an example of a method of manufacturing the shunt resistance according to the first embodiment of the present disclosure;

FIG. 4 is a sectional view illustrating an example of the method of manufacturing the shunt resistance according to the first embodiment of the present disclosure;

FIG. 5 is a sectional view illustrating an example of the method of manufacturing the shunt resistance according to the first embodiment of the present disclosure;

FIG. 6 is a plan view illustrating a semiconductor device according to the first embodiment of the present disclosure;

FIG. 7 is a bottom view illustrating the semiconductor device according to the first embodiment of the present disclosure;

FIG. 8 is a sectional view taken along a line VIII-VIII in FIG. 6;

FIG. 9 is a sectional view taken along a line IX-IX in FIG. 6;

FIG. 10 is a sectional view taken along a line X-X in FIG. 6;

FIG. 11 is a sectional view taken along a line XI-XI in FIG. 6;

FIG. 12 is a circuit diagram illustrating the semiconductor device according to the first embodiment of the present disclosure; and

FIG. 13 is a sectional view illustrating another example of the shunt resistance according to the first embodiment of the present disclosure.

### DETAILED DESCRIPTION

A preferred embodiment of the present disclosure will hereinafter be described specifically with reference to the drawings.

Such terms as “first,” “second,” and “third” in the present disclosure are used simply for identification, and permutation is not intended to be applied to target objects of these terms.

In the present disclosure, unless otherwise noted, a “certain object A being formed in a certain object B” and the “certain object A being formed on the certain object B” include the “certain object A being directly formed in the certain object B” and the “certain object A being formed in the certain object B while another object is interposed between the certain object A and the certain object B.” Similarly, unless otherwise noted, the “certain object A being disposed at the certain object B” and the “certain object A being disposed on the certain object B” include the “certain object A being directly disposed at the certain object B” and the “certain object A being disposed at the certain object B while another object is interposed between the certain object A and the certain object B.” Similarly, unless otherwise noted, the “certain object A being located on the certain object B” includes the “certain object A being located on the certain object B with the certain object A in contact with the certain object B” and the “certain object A being located on the certain object B while another object is interposed between the certain object A and the certain object B.” In addition, unless otherwise noted, the “certain object A being superposed on the certain object B as viewed in a certain direction” includes the “certain object A being superposed on all of the certain object B” and the “certain object A being superposed on a part of the certain object B.” In addition, a “certain surface A facing in a direction B (one side or another side of the direction B)” in the present disclosure is not limited to a case where the angle of the surface A with respect to the direction B is 90°, and includes a case where the surface A is inclined with respect to the direction B.

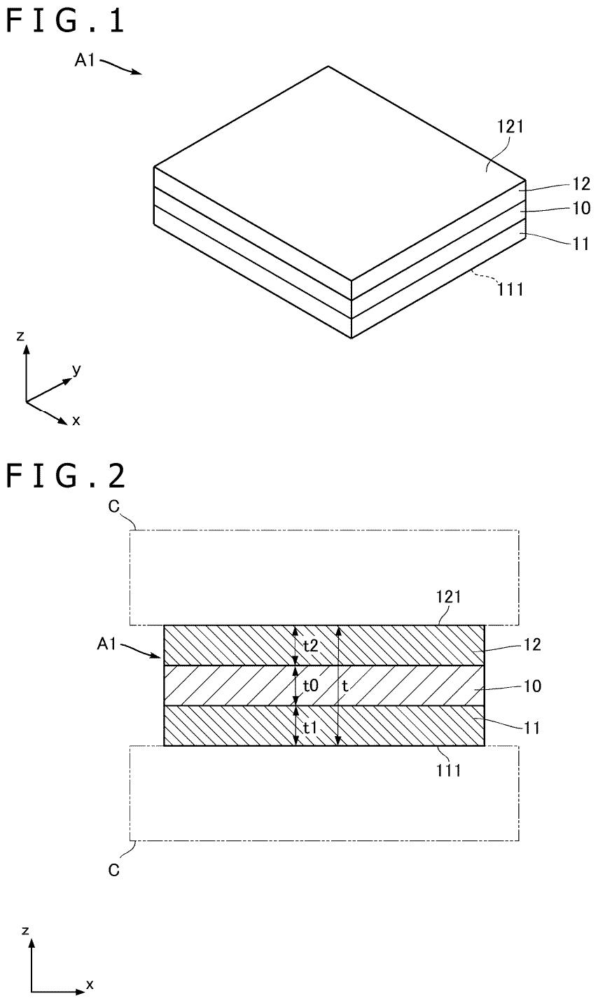

FIG. 1 and FIG. 2 illustrate a shunt resistance according to a first embodiment of the present disclosure. A shunt resistance A1 according to the present embodiment includes a resistive element layer 10, a first electrode layer 11, and a second electrode layer 12. The shape of the shunt resistance A1 is not limited to any shape at all, and is a rectangular shape having two sides extending in an x-direction or a y-direction as viewed in a z-direction, for example. A thickness t of the shunt resistance A1 is not limited to any value at all, and is equal to or more than 0.7 mm but equal to or less than 5.0 mm, for example. In addition, the area of the shunt resistance A1 as viewed in the z-direction is not limited to any value at all, and is equal to or more than 10 mm² but equal to or less than 50 mm², for example.

The resistive element layer 10 is a main member that determines the resistance value of the shunt resistance A1. The resistive element layer 10 has the z-direction as a thickness direction thereof, and has a flat plate shape extending along the x-direction and the y-direction. A thickness t0 of the resistive element layer 10 is not limited to any value at all, and is equal to or more than 0.5 mm but equal to or less than 2.0 mm, for example. In the present embodiment, the resistive element layer 10 has a rectangular shape as viewed in the z-direction.

A material of the resistive element layer 10 is selected as appropriate according to, for example, the resistance value that the shunt resistance A1 is to have, a usage environment of the shunt resistance A1, and others. An example of the material of the resistive element layer 10 is a copper-based alloy or a nichrome-based alloy, and is, specifically, a Cu—Mn—Sn alloy (Zeranin: registered trademark), a Cu—Mn—Ni alloy (Manganin: registered trademark), a Cu—Ni alloy (GCN49: Tokyo Resistance Wire Co., Ltd.), or a Ni—Cr alloy (NCH-1: Tokyo Resistance Wire Co., Ltd.).

The first electrode layer 11 is laminated on a first side (lower side in FIG. 2) in the z-direction of the resistive element layer 10. A material of the first electrode layer 11 has an electric resistivity lower than that of the material of the resistive element layer 10. The material of the first electrode layer 11 is not limited to any kind at all. An example of the material of the first electrode layer 11 is such metal as copper (Cu), silver (Ag), gold (Au), nickel (Ni), or tin (Sn), or alloys thereof.

A thickness t1 of the first electrode layer 11 is not limited to any value at all, and is equal to or more than 0.1 mm but equal to or less than 1.0 mm, for example. In addition, the shape and size of the first electrode layer 11 may be the same as those of the resistive element layer 10, or may be different from those of the resistive element layer 10. In the present embodiment, the first electrode layer 11 has a rectangular shape as viewed in the z-direction. As viewed in the z-direction, the outer edge of the resistive element layer 10 and the outer edge of the first electrode layer 11 coincide with each other. That is, the shape and size of the first electrode layer 11 as viewed in the z-direction are the same as those of the resistive element layer 10.

The first electrode layer 11 has a first mounting surface 111. The first mounting surface 111 faces the first side in the z-direction. As illustrated in FIG. 2, the first mounting surface 111 is used when the shunt resistance A1 is mounted in a mounting target object C.

The second electrode layer 12 is laminated on a second side (upper side in FIG. 2) in the z-direction of the resistive element layer 10. A material of the second electrode layer 12 has an electric resistivity lower than that of the material of the resistive element layer 10. The material of the second electrode layer 12 is not limited to any kind at all. An example of the material of the second electrode layer 12 is such metal as Cu, Ag, Au, Ni, or Sn, or alloys thereof.

A thickness t2 of the second electrode layer 12 is not limited to any value at all, and is equal to or more than 0.1 mm but equal to or less than 2.0 mm, for example. In addition, the shape and size of the second electrode layer 12 may be the same as those of the resistive element layer 10, or may be different from those of the resistive element layer 10. In the present embodiment, the second electrode layer 12 has a rectangular shape as viewed in the z-direction. As viewed in the z-direction, the outer edge of the resistive element layer 10 and the outer edge of the second electrode layer 12 coincide with each other. That is, the shape and size of the second electrode layer 12 as viewed in the z-direction are the same as those of the resistive element layer 10.

The second electrode layer 12 has a second mounting surface 121. The second mounting surface 121 faces the second side in the z-direction. As illustrated in FIG. 2, the second mounting surface 121 is used when the shunt resistance A1 is mounted in the mounting target object C.

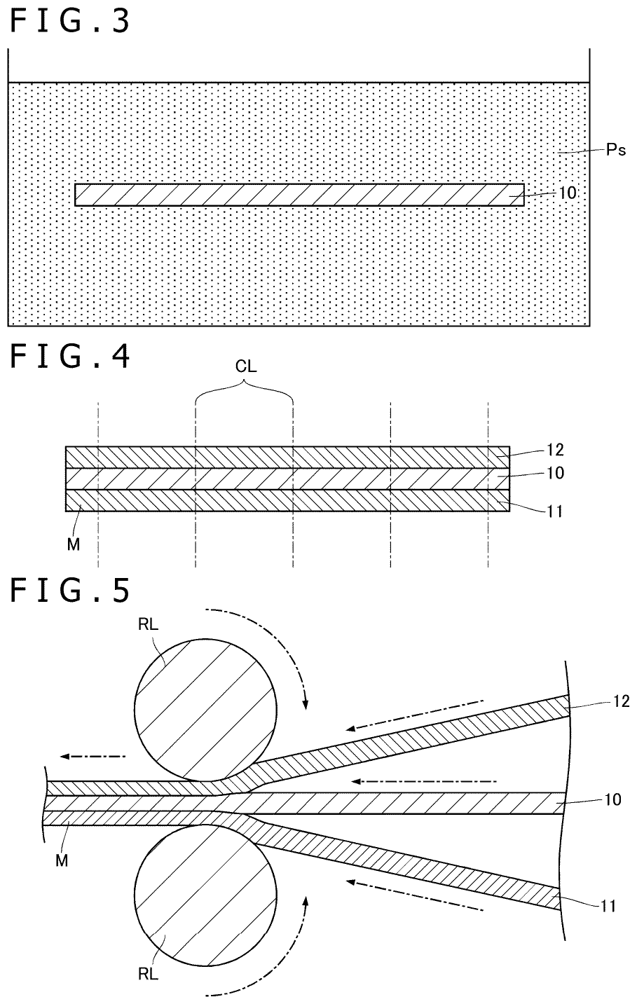

An example of a method of manufacturing the shunt resistance A1 will next be described in the following with reference to FIG. 3 and FIG. 4.

First, as illustrated in FIG. 3, the resistive element layer 10 is prepared. In the present example, the resistive element layer 10 has such a size that a plurality of shunt resistances A1 can be formed. Next, the resistive element layer 10 is immersed in a plating solution Ps. Then, a metal layer is formed on both surfaces of the resistive element layer 10 by a method of electroplating, for example. One of these metal layers becomes the first electrode layer 11. The other becomes the second electrode layer 12. A laminated metallic material M illustrated in FIG. 4 is thus obtained.

Next, the laminated metallic material M is divided into individual pieces by being subjected to cutting processing along cutting lines CL. A plurality of shunt resistances A1 are thereby obtained.

Another example of the method of manufacturing the shunt resistance A1 will next be described in the following with reference to FIG. 5.

First, as illustrated in FIG. 5, the resistive element layer 10, the first electrode layer 11, and the second electrode layer 12 are prepared. The resistive element layer 10, the first electrode layer 11, and the second electrode layer 12 have such a size that a plurality of shunt resistances A1 can be formed. Next, the first electrode layer 11 is disposed on the first side in the thickness direction of the resistive element layer 10, and the second electrode layer 12 is disposed on the second side in the thickness direction of the resistive element layer 10. Then, the resistive element layer 10, the first electrode layer 11, and the second electrode layer 12 are compression-bonded.

A specific method of this compression bonding is not limited to any kind at all, and adopted in the present example is a method which rolls the resistive element layer 10, the first electrode layer 11, and the second electrode layer 12 by a roller RL from both sides in the thickness direction of the resistive element layer 10. The laminated metallic material M including the resistive element layer 10, the first electrode layer 11, and the second electrode layer 12 is obtained by performing the rolling processing using the roller RL.

Thereafter, a plurality of shunt resistances A1 are obtained by, for example, dividing the laminated metallic material M illustrated in FIG. 4 into individual pieces.

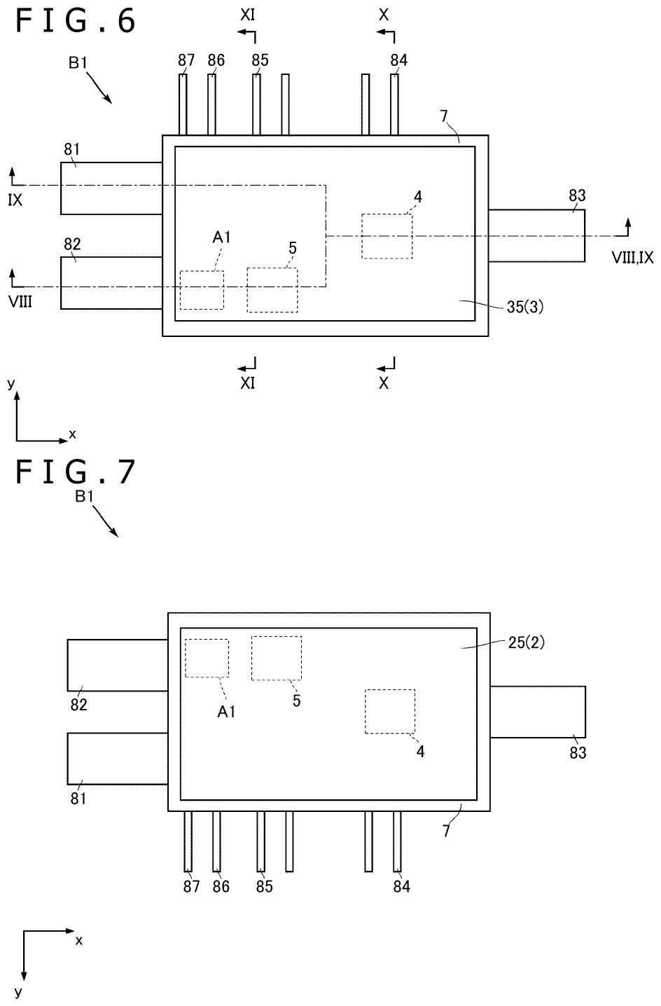

FIGS. 6 to 12 illustrate an example of a semiconductor device in which the shunt resistance A1 is used. A semiconductor device B1 according to the present embodiment includes the shunt resistance A1, a first substrate 2, a second substrate 3, a first switching element 4, and a second switching element 5. In addition, the semiconductor device B1 further includes a positive electrode terminal 81, a negative electrode terminal 82, an output terminal 83, a first gate terminal 84, a second gate terminal 85, and detection terminals 86 and 87.

There are no limitations at all on specific applications, for example, of the semiconductor device B1. In the semiconductor device B1, the first switching element 4 constitutes an upper arm circuit, and the second switching element 5 constitutes a lower arm circuit. A half-bridge circuit is thereby formed. The semiconductor device B1 constitutes, for example, an inverter for converting direct-current power into alternating-current power and supplying the power to a driving source such as a motor. Description will be made by taking as an example a case where the semiconductor device B1 according to the present embodiment includes one half-bridge circuit. However, the semiconductor device B1 may include, for example, three half-bridge circuits to supply power to what is generally called a three-phase alternating-current motor.

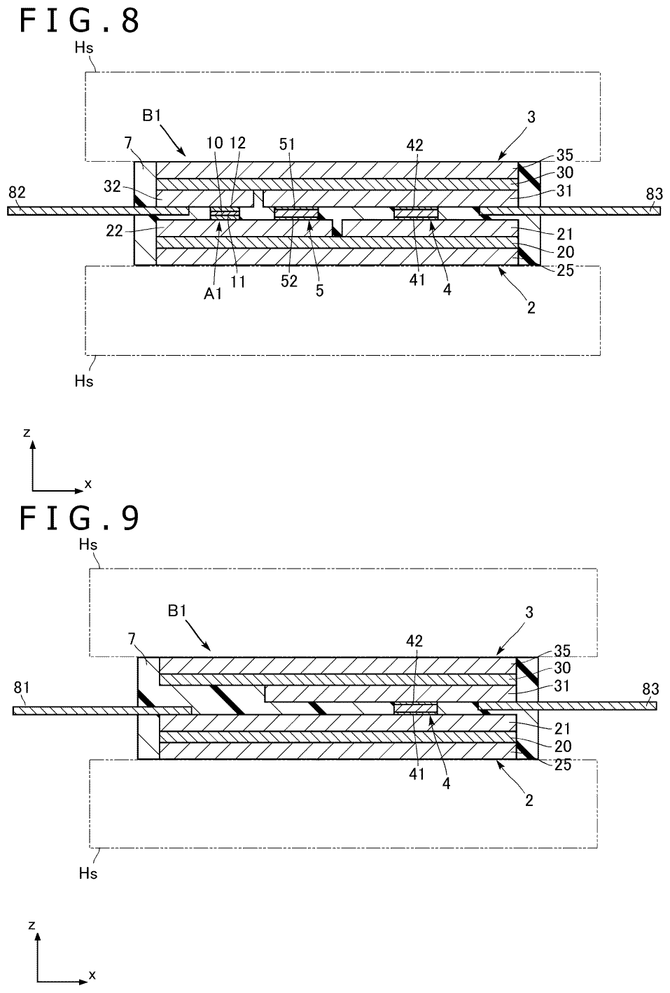

As illustrated in FIG. 8 and FIG. 9, the first substrate 2 includes a first conductive layer 21, a third conductive layer 22, a first insulating layer 20, and a first metal layer 25, and is configured as, for example, a direct bonded copper (DBC) substrate or an active metal brazing (AMB) substrate. The first conductive layer 21 is a layer having the z-direction as a thickness direction thereof. The first conductive layer 21 includes Cu, for example. The third conductive layer 22 is separated from the first conductive layer 21. The third conductive layer 22 is a layer having the z-direction as a thickness direction thereof. The third conductive layer 22 includes Cu, for example. It is to be noted that the first substrate 2 is not limited to the above-described configuration, and may have a configuration in which the first insulating layer 20 and the first metal layer 25 are not provided, for example.

The first insulating layer 20 is a layer having the z-direction as a thickness direction thereof. The first insulating layer 20 has an insulating property. The first insulating layer 20 is formed of ceramic, for example.

The first metal layer 25 is a layer having the z-direction as a thickness direction thereof. The first metal layer 25 is laminated on an opposite side in the z-direction of the first insulating layer 20 from the first conductive layer 21 and the third conductive layer 22. The first metal layer 25 includes Cu, for example.

The first substrate 2 is not limited to the above-described configuration, and may have a configuration in which the first insulating layer 20 and the first metal layer 25 are not provided, for example.

The second substrate 3 includes a second conductive layer 31, a fourth conductive layer 32, a second insulating layer 30, and a second metal layer 35, and is configured as, for example, a DBC substrate or an AMB substrate. The second conductive layer 31 is a layer having the z-direction as a thickness direction thereof. The second conductive layer 31 includes Cu, for example. The fourth conductive layer 32 is separated from the second conductive layer 31. The fourth conductive layer 32 is a layer having the z-direction as a thickness direction thereof. The fourth conductive layer 32 includes Cu, for example.

The second insulating layer 30 is a layer having the z-direction as a thickness direction thereof. The second insulating layer 30 has an insulating property. The second insulating layer 30 is formed of ceramic, for example.

The second metal layer 35 is a layer having the z-direction as a thickness direction thereof. The second metal layer 35 is laminated on an opposite side in the z-direction of the second insulating layer 30 from the second conductive layer 31 and the fourth conductive layer 32. The second metal layer 35 includes Cu, for example.

The second substrate 3 is not limited to the above-described configuration, and may have a configuration in which the second insulating layer 30 and the second metal layer 35 are not provided, for example.

The first conductive layer 21 and the second conductive layer 31 at least partly face each other in the z-direction. In addition, a part of the third conductive layer 22 and a part of the second conductive layer 31 face each other in the z-direction. In addition, the third conductive layer 22 and the fourth conductive layer 32 at least partly face each other in the z-direction.

A plurality of first switching elements 4 are formed by use of a semiconductor material. The semiconductor material may be, for example, silicon carbide (SiC), silicon (Si), gallium arsenide (GaAs), gallium nitride (GaN), or another material. In addition, in the present embodiment, each of the first switching elements 4 is a metal-oxide-semiconductor field-effect transistor (MOSFET). It is to be noted that the plurality of first switching elements 4 are not limited to the MOSFET, and may be a FET including a metal-insulator-semiconductor FET (MISFET), for example. The first switching elements 4 each include a first drain electrode 41, a first source electrode 42, and a first gate electrode 43. The first drain electrode 41 is disposed on an opposite side in the z-direction from the first source electrode 42 and the first gate electrode 43.

The first switching element 4 is disposed between the first conductive layer 21 and the second conductive layer 31 in the z-direction. The first drain electrode 41 is conductively bonded to the first conductive layer 21. The first source electrode 42 is conductively bonded to the second conductive layer 31. A method of the abovementioned conductive bonding is not limited to any kind at all, and, for example, solder bonding, bonding using a fired silver material, solid phase diffusion bonding, or another method of conductive bonding is used as appropriate.

A plurality of second switching elements 5 are formed by use of a semiconductor material. The semiconductor material may be, for example, SiC, Si, GaAs, GaN, or another material. In addition, in the present embodiment, each of the second switching elements 5 is a MOSFET. It is to be noted that the plurality of second switching elements 5 are not limited to the MOSFET, and may be a FET including a MISFET, for example. The second switching elements 5 each include a second drain electrode 51, a second source electrode 52, and a second gate electrode 53. The second drain electrode 51 is disposed on an opposite side in the z-direction from the second source electrode 52 and the second gate electrode 53.

The second switching element 5 is disposed between the third conductive layer 22 and the second conductive layer 31 in the z-direction. The second drain electrode 51 is conductively bonded to the second conductive layer 31. The second source electrode 52 is conductively bonded to the third conductive layer 22. A method of the abovementioned conductive bonding is not limited to any kind at all, and, for example, solder bonding, bonding using a fired silver material, solid phase diffusion bonding, or another method of conductive bonding is used as appropriate.

As illustrated in FIG. 9, the positive electrode terminal 81 is conductively bonded to the first conductive layer 21. A method of this conductive bonding is not limited to any kind at all, and, for example, solder bonding, bonding using a fired silver material, laser welding, solid phase diffusion bonding, or another method of conductive bonding is used as appropriate. The positive electrode terminal 81 includes Cu, for example.

As illustrated in FIG. 8, the negative electrode terminal 82 is conductively bonded to the fourth conductive layer 32. A method of this conductive bonding is not limited to any kind at all, and, for example, solder bonding, bonding using a fired silver material, laser welding, solid phase diffusion bonding, or another method of conductive bonding is used as appropriate. The negative electrode terminal 82 includes Cu, for example.

As illustrated in FIG. 8 and FIG. 9, the output terminal 83 is conductively bonded to the second conductive layer 31. A method of this conductive bonding is not limited to any kind at all, and, for example, solder bonding, bonding using a fired silver material, laser welding, solid phase diffusion bonding, or another method of conductive bonding is used as appropriate. The output terminal 83 includes Cu, for example.

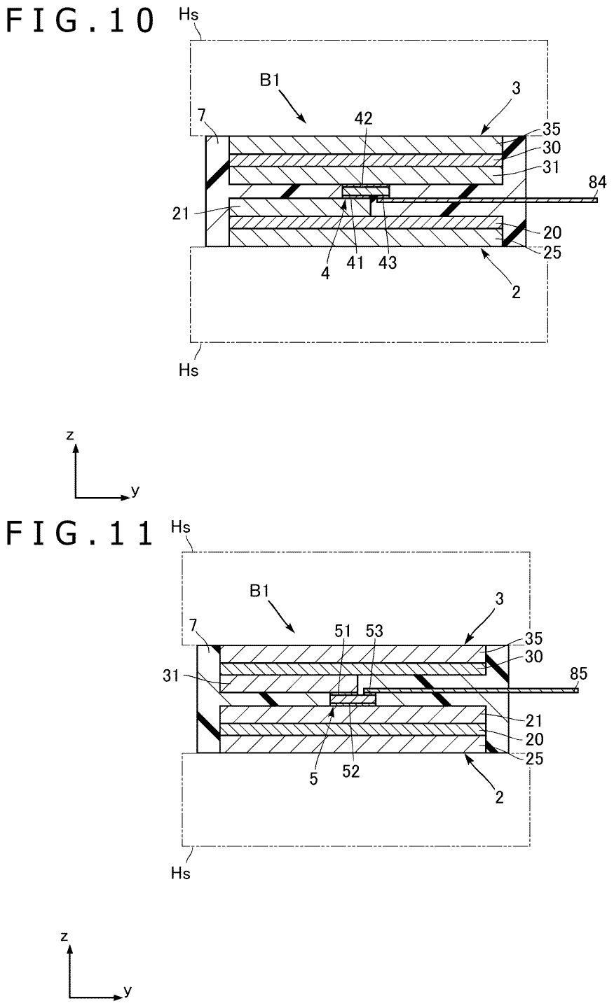

As illustrated in FIG. 10, the first gate terminal 84 is conductively bonded to the first gate electrode 43 of the first switching element 4. A method of this conductive bonding is not limited to any kind at all, and, for example, solder bonding, bonding using a fired silver material, solid phase diffusion bonding, or another method of conductive bonding is used as appropriate.

As illustrated in FIG. 11, the second gate terminal 85 is conductively bonded to the second gate electrode 53 of the second switching element 5. A method of this conductive bonding is not limited to any kind at all, and, for example, solder bonding, bonding using a fired silver material, solid phase diffusion bonding, or another method of conductive bonding is used as appropriate.

As illustrated in FIG. 8, the shunt resistance A1 is disposed between the first substrate 2 and the second substrate 3 in the z-direction. The shunt resistance A1 is electrically disposed on a conduction path of a current switched by at least one of the first switching element 4 and the second switching element 5. In the present embodiment, the shunt resistance A1 is disposed between the third conductive layer 22 and the fourth conductive layer 32. The first mounting surface 111 of the first electrode layer 11 is conductively bonded to the third conductive layer 22. In addition, the second mounting surface 121 of the second electrode layer 12 is conductively bonded to the fourth conductive layer 32. A method of the abovementioned conductive bonding is not limited to any kind at all, and, for example, solder bonding, bonding using a fired silver material, solid phase diffusion bonding, or another method of conductive bonding is used as appropriate.

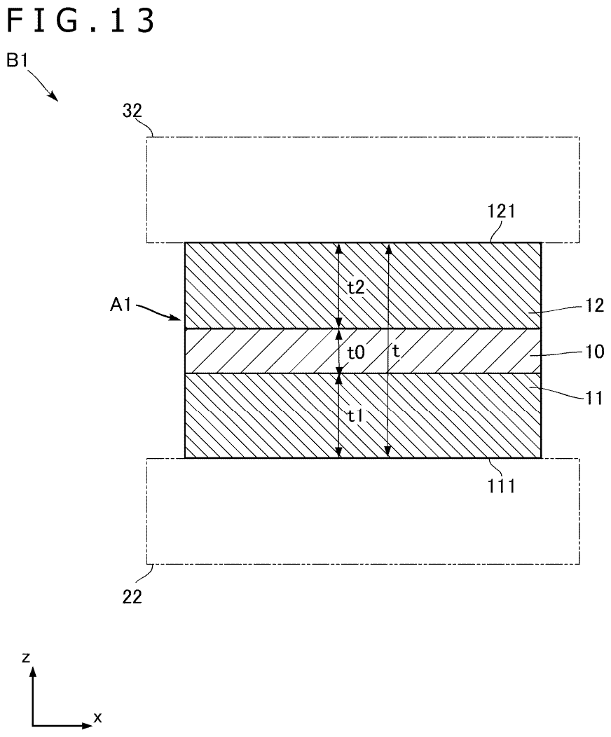

The shunt resistance A1 may have a configuration illustrated in FIG. 13 in a case where, for example, a distance in the z-direction between the third conductive layer 22 and the fourth conductive layer 32 is relatively large in order to arrange the first switching element 4, the second switching element 5, the first gate terminal 84, and the second gate terminal 85, for example, between the first substrate 2 and the second substrate 3. In the present example, the thickness t1 of the first electrode layer 11 and the thickness t2 of the second electrode layer 12 are larger than the thickness t0 of the resistive element layer 10. The thickness t of the shunt resistance A1 can thus be increased. Even when the thickness t1 and the thickness t2 are increased, the resistance value of the shunt resistance A1 can be maintained at a desired value unless the thickness t0 of the resistive element layer 10 is changed.

The detection terminals 86 and 87 are terminals used for current detection using the shunt resistance A1. The detection terminal 86 is, for example, conductively bonded to the third conductive layer 22. The detection terminal 87 is, for example, conductively bonded to the fourth conductive layer 32.

A sealing resin 7 covers at least a part of each of the first substrate 2, the second substrate 3, the first switching element 4, the second switching element 5, the positive electrode terminal 81, the negative electrode terminal 82, the output terminal 83, the first gate terminal 84, the second gate terminal 85, and the detection terminals 86 and 87. The sealing resin 7 has an insulating property. The sealing resin 7 includes epoxy resin, for example.

A part of each of the positive electrode terminal 81, the negative electrode terminal 82, the output terminal 83, the first gate terminal 84, the second gate terminal 85, and the detection terminals 86 and 87 projects from the sealing resin 7. However, there are no limitations at all on specific configurations of the positive electrode terminal 81, the negative electrode terminal 82, the output terminal 83, the first gate terminal 84, the second gate terminal 85, and the detection terminals 86 and 87, and various configurations can be adopted as long as the configurations allow electric connection to the outside.

One surface of each of the first metal layer 25 and the second metal layer 35 is exposed from the sealing resin 7.

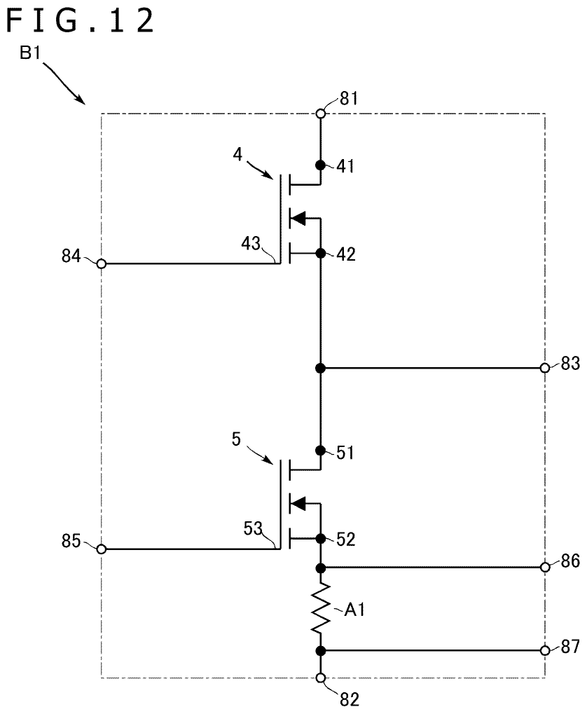

FIG. 12 is a circuit diagram illustrating the semiconductor device B1. As illustrated in the figure, the first switching element 4 constitutes an upper arm circuit, and the second switching element 5 constitutes a lower arm circuit. The positive electrode terminal 81 and the negative electrode terminal 82 are terminals to which direct-current power is input. The output terminal 83 is a terminal connected to a driving source supplied with alternating-current power, for example. In the present embodiment, the shunt resistance A1 is electrically disposed between the negative electrode terminal 82 and the second switching element 5, and is electrically disposed on a conduction path of a current switched by the second switching element 5. Incidentally, unlike in the present embodiment, the shunt resistance A1 may be electrically disposed on a conduction path of a current switched by the first switching element 4, by being electrically disposed between the positive electrode terminal 81 and the first switching element 4.

In a case where a three-phase alternating current motor is supplied with power, a configuration which includes three sets of the first switching element 4, the second switching element 5, and the output terminal 83 may be adopted.

The first gate terminal 84 is a terminal for the switching control of the first switching element 4. The second gate terminal 85 is a terminal for the switching control of the second switching element 5.

The detection terminals 86 and 87 are terminals for electrically connecting, in parallel with the shunt resistance A1, a detector (not illustrated) for detecting a current flowing through the shunt resistance A1.

Actions of the shunt resistance A1 and the semiconductor device B1 will next be described.

According to the present embodiment, the shunt resistance A1 has the first electrode layer 11 and the second electrode layer 12 arranged on both sides in the thickness direction with the resistive element layer 10 interposed therebetween. Thus, as illustrated in FIG. 2, the mounting target object C of the shunt resistance A1 can be disposed on both sides in the z-direction of the shunt resistance A1. Hence, it is possible to reduce the size in the x-direction and the y-direction of a mounting structural body including the mounting target object C in which the shunt resistance A1 is mounted.

The first electrode layer 11 has the first mounting surface 111. The second electrode layer 12 has the second mounting surface 121. Thus, the mounting target object C is disposed in such a manner as to be superposed on the shunt resistance A1 as viewed in the z-direction. This is preferable in reducing the size in the x-direction and the y-direction of the mounting structural body described above.

The semiconductor device B1 has the shunt resistance A1 disposed between the first substrate 2 and the second substrate 3 in the z-direction. It is thus possible to avoid an increase in the size in the x-direction or the y-direction due to the provision of the shunt resistance A1 in the semiconductor device B1. Hence, a miniaturization of the semiconductor device B1 can be achieved.

The shunt resistance, the method of manufacturing the shunt resistance, and the semiconductor device according to an embodiment of the present disclosure are not limited to those in the foregoing embodiment. The specific configurations of the shunt resistance, the method of manufacturing the shunt resistance, and the semiconductor device according to an embodiment of the present disclosure are capable of being changed in design in various manners.

### Supplement 1

A shunt resistance including:
a resistive element layer;
a first electrode layer laminated on a first side in a thickness direction of the resistive element layer; and
a second electrode layer laminated on a second side in the thickness direction of the resistive element layer.

### Supplement 2

The shunt resistance according to supplement 1, in which the first electrode layer has a first mounting surface that faces the first side in the thickness direction.

### Supplement 3

The shunt resistance according to supplement 2, in which the second electrode layer has a second mounting surface that faces the second side in the thickness direction.

### Supplement 4

The shunt resistance according to supplement 3, in which,
as viewed in the thickness direction, an outer edge of the resistive element layer and an outer edge of the first electrode layer coincide with each other.

### Supplement 5

The shunt resistance according to supplement 3 or 4, in which,
as viewed in the thickness direction, an outer edge of the resistive element layer and an outer edge of the second electrode layer coincide with each other.

### Supplement 6

The shunt resistance according to any one of supplements 3 to 5, in which
the resistive element layer includes a copper-based alloy or a nichrome-based alloy.

### Supplement 7

The shunt resistance according to any one of supplements 3 to 6, in which
the first electrode layer includes at least one of copper, silver, gold, and nickel.

### Supplement 8

The shunt resistance according to any one of supplements 3 to 7, in which
the second electrode layer includes at least one of copper, silver, gold, and nickel.

### Supplement 9

A semiconductor device including:
a first substrate including a first conductive layer;
a second substrate including a second conductive layer;
a first switching element including a first drain electrode, a first source electrode, and a first gate electrode and constituting an upper arm circuit;
a second switching element including a second drain electrode, a second source electrode, and a second gate electrode and constituting a lower arm circuit; and
the shunt resistance according to any one of supplements 3 to 8,
the first conductive layer and the second conductive layer facing each other in a thickness direction,
the first drain electrode being conductively bonded to the first conductive layer,
the second drain electrode being conductively bonded to the second conductive layer,
the first source electrode and the second conductive layer being electrically connected to each other, and
the shunt resistance being disposed between the first substrate and the second substrate in the thickness direction, and being electrically disposed on a conduction path of a current switched by at least one of the first switching element and the second switching element.

### Supplement 10

The semiconductor device according to supplement 9, in which
the first substrate further includes a third conductive layer that faces the second conductive layer in the thickness direction,
the second substrate further includes a fourth conductive layer that faces the third conductive layer in the thickness direction,
the first mounting surface is conductively bonded to the third conductive layer, and
the second mounting surface is conductively bonded to the fourth conductive layer.

### Supplement 11

The semiconductor device according to supplement 9 or 10, in which
the first substrate includes a first metal layer located on an opposite side from the first conductive layer in the thickness direction and a first insulating layer interposed between the first conductive layer and the first metal layer, and
the second substrate includes a second metal layer located on an opposite side from the second conductive layer in the thickness direction and a second insulating layer interposed between the second conductive layer and the second metal layer.

### Supplement 12

The semiconductor device according to supplement 11, further including:
a sealing resin that covers the first switching element, the second switching element, the first conductive layer, and the second conductive layer,
in which the first metal layer and the second metal layer are exposed from the sealing resin.

### Supplement 13

A method of manufacturing a shunt resistance, the method including:
a step of preparing a resistive element layer;
a step of forming a laminated metallic material, by forming a first electrode layer by plating on a first side in a thickness direction of the resistive element layer and forming a second electrode layer by plating on a second side in the thickness direction of the resistive element layer; and
a step of dividing the laminated metallic material into individual pieces.

### Supplement 14

A method of manufacturing a shunt resistance, the method including:
a step of forming a laminated metallic material by compression-bonding a resistive element layer, a first electrode layer located on a first side in a thickness direction of the resistive element layer, and a second electrode layer located on a second side in the thickness direction of the resistive element layer; and
a step of dividing the laminated metallic material into individual pieces.

What is claimed is:

1. A shunt resistance comprising:
a resistive element layer;
a first electrode layer laminated on a first side in a thickness direction of the resistive element layer; and
a second electrode layer laminated on a second side in the thickness direction of the resistive element layer.

2. The shunt resistance according to claim 1, wherein
the first electrode layer has a first mounting surface that faces the first side in the thickness direction.

3. The shunt resistance according to claim 2, wherein
the second electrode layer has a second mounting surface that faces the second side in the thickness direction.

4. The shunt resistance according to claim 3, wherein,
as viewed in the thickness direction, an outer edge of the resistive element layer and an outer edge of the first electrode layer coincide with each other.

5. The shunt resistance according to claim 3, wherein,
as viewed in the thickness direction, an outer edge of the resistive element layer and an outer edge of the second electrode layer coincide with each other.

6. The shunt resistance according to claim 3, wherein
the resistive element layer includes a copper-based alloy or a nichrome-based alloy.

7. The shunt resistance according to claim 3, wherein
the first electrode layer includes at least one of copper, silver, gold, and nickel.

8. The shunt resistance according to claim 3, wherein
the second electrode layer includes at least one of copper, silver, gold, and nickel.

9. A semiconductor device comprising:
a first substrate including a first conductive layer;
a second substrate including a second conductive layer;
a first switching element including a first drain electrode, a first source electrode, and a first gate electrode and constituting an upper arm circuit;
a second switching element including a second drain electrode, a second source electrode, and a second gate electrode and constituting a lower arm circuit; and
the shunt resistance according to claim 3,
the first conductive layer and the second conductive layer facing each other in a thickness direction,
the first drain electrode being conductively bonded to the first conductive layer,
the second drain electrode being conductively bonded to the second conductive layer,
the first source electrode and the second conductive layer being electrically connected to each other, and
the shunt resistance being disposed between the first substrate and the second substrate in the thickness direction, and being electrically disposed on a conduction path of a current switched by at least one of the first switching element and the second switching element.

10. The semiconductor device according to claim 9, wherein
the first substrate further includes a third conductive layer that faces the second conductive layer in the thickness direction,
the second substrate further includes a fourth conductive layer that faces the third conductive layer in the thickness direction,
the first mounting surface is conductively bonded to the third conductive layer, and
the second mounting surface is conductively bonded to the fourth conductive layer.

11. The semiconductor device according to claim 9, wherein
the first substrate includes a first metal layer located on an opposite side from the first conductive layer in the thickness direction and a first insulating layer interposed between the first conductive layer and the first metal layer, and
the second substrate includes a second metal layer located on an opposite side from the second conductive layer in the thickness direction and a second insulating layer interposed between the second conductive layer and the second metal layer.

12. The semiconductor device according to claim 11, further comprising:
a sealing resin that covers the first switching element, the second switching element, the first conductive layer, and the second conductive layer,
wherein the first metal layer and the second metal layer are exposed from the sealing resin.

13. A method of manufacturing a shunt resistance, the method comprising:
preparing a resistive element layer;
forming a laminated metallic material, by forming a first electrode layer by plating on a first side in a thickness direction of the resistive element layer and forming a second electrode layer by plating on a second side in the thickness direction of the resistive element layer; and
dividing the laminated metallic material into individual pieces.

14. A method of manufacturing a shunt resistance, the method comprising:
forming a laminated metallic material by compression-bonding a resistive element layer, a first electrode layer located on a first side in a thickness direction of the resistive element layer, and a second electrode layer located on a second side in the thickness direction of the resistive element layer; and
dividing the laminated metallic material into individual pieces.
